(19) United States
(12) Patent Application Publication
(10) Pub. No.: US 2025/0275467 A1
(43) Pub. Date: Aug. 28, 2025

(54) LIGHT-EMITTING DIODE AND DISPLAY DEVICE COMPRISING THE SAME

(71) Applicant: Samsung Display Co., LTD., Yongin-si (KR)

(72) Inventors: Gyehyun Park, Yongin-si (KR); Gyu Bong KIM, Yongin-si (KR); Sang Hee YU, Yongin-si (KR); YUNHYUK KO, Yongin-si (KR); WON-JUN PARK, Yongin-si (KR); CHUL SOON PARK, Yongin-si (KR); Dong-Woo SHIN, Yongin-si (KR); JUNGHWAN LIM, Yongin-si (KR)

(21) Appl. No.: 18/938,680

(22) Filed: Nov. 6, 2024

(30) Foreign Application Priority Data
Feb. 27, 2024 (KR) 10-2024-0028142

(51) Int. Cl. H10K 85/60; C09K 11/54; H10K 50/115; H10K 50/16

(52) U.S. Cl. CPC H10K 85/60; C09K 11/54; H10K 50/115; H10K 50/16

(57) ABSTRACT

A display device includes a first electrode, a hole transport layer disposed on the first electrode, a light-emitting layer disposed on the hole transport layer, an electron transport layer disposed on the light-emitting layer, and a second electrode disposed on the electron transport layer, wherein the electron transport layer includes a metal oxide composition, the metal oxide composition includes a solvent and a metal oxide, the solvent includes a first compound represented by at least one of Chemical Formulas 1 to 3, and the metal oxide includes a second compound represented by Chemical Formula 4.

This application claims priority to Korean Patent Application No. 10-2024-0028142, filed on Feb. 27, 2024, and all the benefits accruing therefrom under 35 U.S.C. § 119, the content of which in its entirety is herein incorporated by reference.

### BACKGROUND

### (a) Field

The disclosure relates to a light-emitting element and a display device including the same.

### (b) Description of the Related Art

In a light-emitting element, holes supplied from the anode and electrons supplied from the cathode combine within a light-emitting layer formed between the anode and the cathode to form an exciton, and this exciton is stabilized to emit light.

Light-emitting elements have various advantages such as wide viewing angle, fast response speed, thinness, and low power consumption, so they are widely applied to various electrical and electronic devices such as televisions, monitors, and mobile phones.

### SUMMARY

Embodiments are intended to provide a display device with improved luminous efficiency and reliability of a light-emitting element and a method of manufacturing the display device.

A display device in an embodiment of the disclosure includes a first electrode, a hole transport layer disposed on the first electrode, the light-emitting layer disposed on the hole transport layer, an electron transport layer disposed on the light-emitting layer, and a second electrode disposed on the electron transport layer. The electron transport layer includes a metal oxide composition, the metal oxide composition includes a solvent and a metal oxide, and the solvent includes a first compound represented by at least one of the following Chemical Formulas 1 to 3:

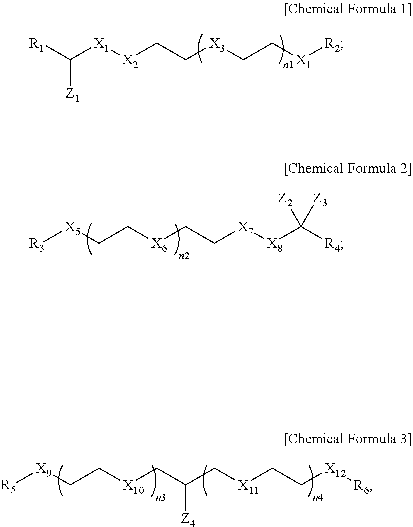

the metal oxide includes a second compound represented by following Chemical Formula 4:

MₚO_{q} [Chemical Formula 4],

in the Chemical Formulas 1 to 3, R₁, R₂, R₃, R₄, R₅, and R₆ are each independently deuterium, a hydroxyl group, a C₁-C₂₀ alkyl group, a C₁-C₂₀ alkoxy group, a C₃-C₃₀ carbocyclic group, a C₁-C₃₀ heterocyclic group, a C₆-C₃₀ aryloxy group, a C₆-C₃₀ arylthio group, or a substituted or unsubstituted C₁-C₂₀ alkyl group or C₁-C₂₀ alkoxy group with any combinations of deuterium, the hydroxyl group, the C₁-C₂₀ alkyl group, the C₁-C₂₀ alkoxy group, the C₃-C₃₀ carbocyclic group, the C₁-C₃₀ heterocyclic group, the C₆-C₆₀ aryloxy group and the C₆-C₆₀ arylthio group, and X₁ to X₁₂ each are independently a single bond, a substituted or unsubstituted C₁-C₆₀ alkylene group, a substituted or unsubstituted C₂-C₆₀ alkenylene group, a substituted or unsubstituted C₂-C₆₀ alkynylene group, a substituted or unsubstituted C₃-C₁₀ cycloalkylene group, a substituted or unsubstituted C₃-C₁₀ heterocycloalkenylene group, a substituted or unsubstituted C₃-C₁₀ cycloalkenylene group or a substituted or unsubstituted C₁-C₁₀ heterocycloalkenylene group, or *—O—*′, and the above * and *′ are bonding sites with the neighboring atoms, and Z1 to Z4 each are independently hydrogen, deuterium, —F, —Cl, —Br, —I, a hydroxyl group, a cyano group, a nitro group, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₆₀ carbocyclic group, a substituted or unsubstituted C₁-C₆₀ heterocyclic group, a substituted or unsubstituted C₆-C₆₀ aryloxy group, a substituted or unsubstituted C₆-C₆₀ arylthio group, and the n1, n2, n3, and n4, each are independently an integer from 0 to 5, and M in the Chemical Formula 4 is Zn, Ti, Zr, Sn, W, Ta, Ni, Mo, Cu, or V, and p and q in the Chemical Formula 4 are each independently one of integers 1 to 5.

In an embodiment, the molecular weight of the first compound may be 140 grams per mole (g/mol) or more.

In an embodiment, the ratio of a number of oxygen atoms to the total number of carbon atoms and oxygen atoms included in the first compound may be 0.3 or more.

In an embodiment, the first compound may include at least one of a secondary alcohol and a tertiary alcohol.

In an embodiment, the first compound may include at least one of Compounds 1 to 3 below:

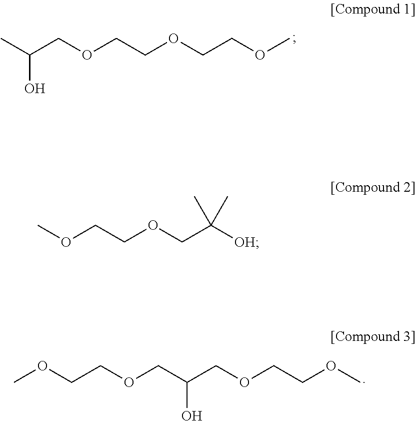

In an embodiment, the first compound may further include any one of compounds 4 to 28 below:

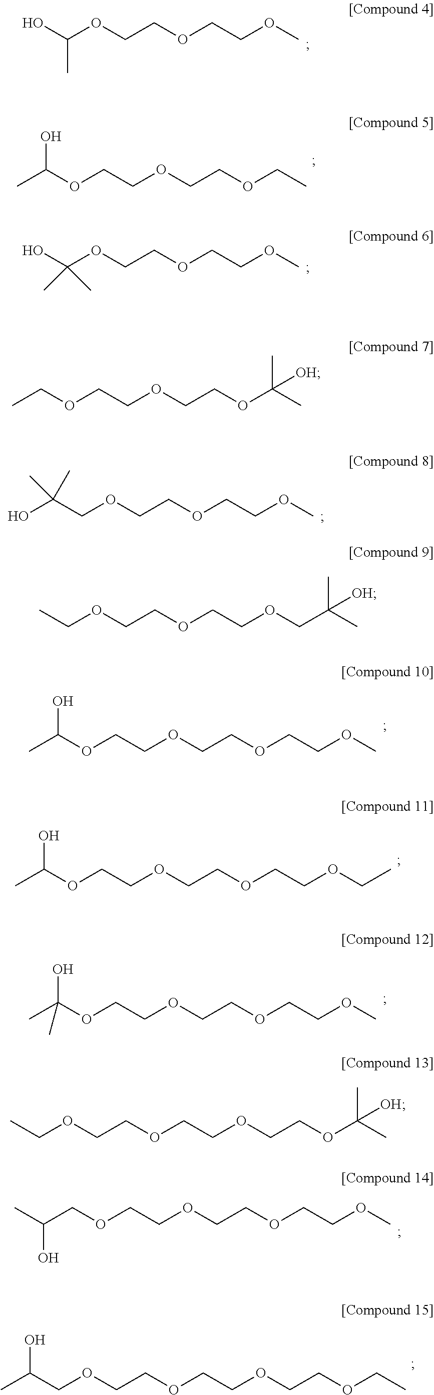

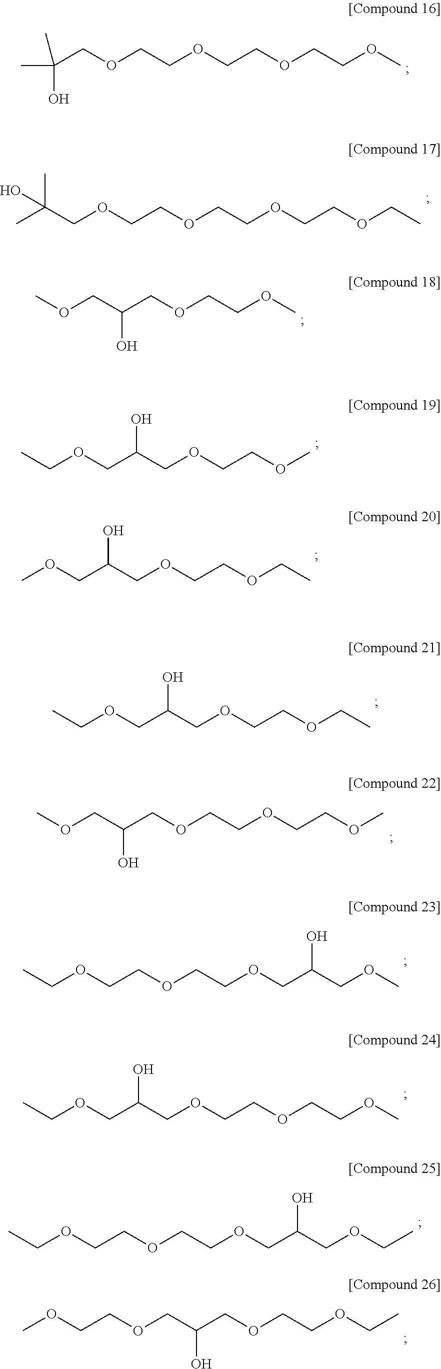

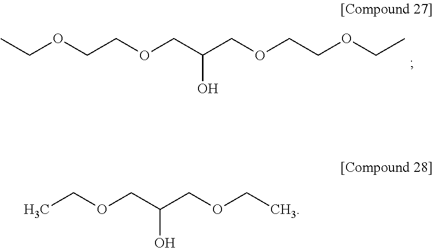

In an embodiment, the second compound may be a zinc-containing oxide.

In an embodiment, the second compound may include at least one of ZnO, ZnMgO, ZnAIO, ZnSiO, ZnYbO, TiO₂, WO₃, W₂O₃, and WO₂.

A light-emitting element in an embodiment of the disclosure includes a first electrode, the hole transport layer disposed on the first electrode, the light-emitting layer disposed on the hole transport layer, the electron transport layer disposed on the light-emitting layer, and the second electrode disposed on the electron transport layer, it includes two electrodes, the electron transport layer includes a metal oxide composition, the metal oxide composition includes a solvent and a metal oxide, the solvent includes a first compound, a molecular weight of the first compound is 140 g/mol or more, the first compound includes at least one of a secondary alcohol and a tertiary alcohol, and a ratio of a number of oxygen atoms to the total number of carbon atoms and oxygen atoms included in the first compound is 0.3 or more.

In an embodiment, the first compound may include at least one of the compounds represented by Chemical Formulas 1 to 3 below:

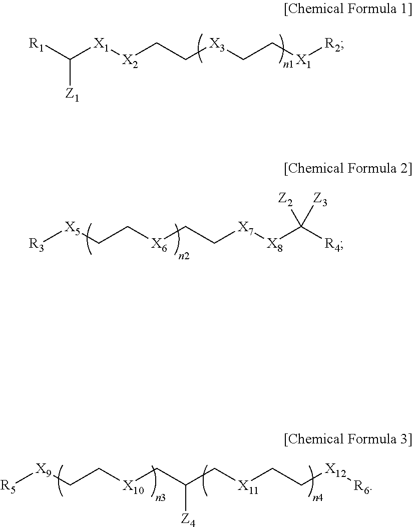

In an embodiment, in Chemical Formulas 1 to 3 above, R₁, R₂, R₃, R₄, R₅, and R₆ are each independently deuterium, a hydroxyl group, a C₁-C₂₀ alkyl group, a C₁-C₂₀ alkoxy group, a C₃-C₃₀ carbocyclic group, a C₁-C₃₀ heterocyclic group, a C₆-C₃₀ aryloxy group, a C₆-C₃₀ arylthio group, or a substituted or unsubstituted C₁-C₂₀ alkyl group or C₁-C₂₀ alkoxy group with any combinations of deuterium, the hydroxyl group, the C₁-C₂₀ alkyl group, the C₁-C₂₀ alkoxy group, the C₃-C₃₀ carbocyclic group, the C₁-C₃₀ heterocyclic group, the C₆-C₃₀ aryloxy group and the C₆-C₃₀ arylthio group, X₁ to X₁₂ are each independently a single bond, a substituted or unsubstituted C₁-C₆₀ alkylene group, a substituted or unsubstituted C₂-C₆₀ alkenylene group, a substituted or unsubstituted C₂-C₆₀ alkynylene group, a substituted or unsubstituted C₃-C₁₀ cycloalkylene group, a substituted or unsubstituted C₃-C₁₀ heterocycloalkenylene group, a substituted or unsubstituted C₃-C₁₀ cycloalkenylene group, a substituted or unsubstituted C₁-C₁₀ heterocycloalkenylene group, or *—O—*′, where * and *′ are bonding sites with the neighboring atoms, Z1 to Z₄ are each independently hydrogen, deuterium, —F, —Cl, —Br, —I, a hydroxyl group, a cyanide group, a nitro group, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₆₀ carbocyclic group, a substituted or unsubstituted C₁-C₆₀ heterocyclic group, a substituted or unsubstituted C₆-C₆₀ aryloxy group, or a substituted or unsubstituted C₆-C₆₀ arylthio group, and n1, n2, n3, and n4 are each independently an integer from 0 to 5.

In an embodiment, the metal oxide includes a second compound, and the second compound may be a zinc-containing oxide.

In an embodiment, the metal oxide includes a second compound, and the second compound may include at least one of ZnO, ZnMgO, ZnAIO, ZnSiO, ZnYbO, TiO₂, WO₃, W₂O₃, and WO₂.

A display device in an embodiment of the disclosure includes a substrate, a transistor disposed on the substrate, and a light-emitting element electrically connected to the transistor, wherein the light-emitting element includes the first electrode and the hole transport layer disposed on the first electrode, the light-emitting layer disposed on the hole transport layer, the electron transport layer disposed on the light-emitting layer, and the second electrode disposed on the electron transport layer, wherein the electron transport layer includes a metal oxide composition, and the metal oxide composition includes a solvent and a metal oxide, wherein the solvent includes a first compound represented by at least one of the following Chemical Formulas 1 to 3:

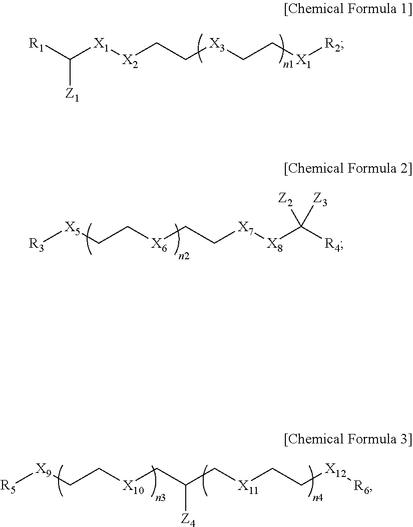

the metal oxide includes a second compound represented by the following Chemical Formula 4:

MₚO_{q} [Chemical Formula 4],

where, in the Chemical Formulas 1 to 3, R₁, R₂, R₃, R₄, R₅, and R₆ each independently represent deuterium, a hydroxyl group, a C₁-C₂₀ alkyl group, a C₁-C₂₀ alkoxy group, a C₃-C₃₀ carbocyclic group, a C₁-C₃₀ heterocyclic group, a C₆-C₃₀ aryloxy group, a C₆-C₃₀ arylthio group, or a substituted or unsubstituted C₁-C₂₀ alkyl group or C₁-C₂₀ alkoxy group with any combinations of deuterium, the hydroxyl group, the C₁-C₂₀ alkyl group, the C₁-C₂₀ alkoxy group, the C₃-C₃₀ carbocyclic group, the C₁-C₃₀ heterocyclic group, the C₆-C₃₀ aryloxy group and the C₆-C₃₀ arylthio group,

X₁ to X₁₂ each independently represent a single bond, a substituted or unsubstituted C₁-C₆₀ alkylene group, a substituted or unsubstituted C₂-C₆₀ alkenylene group, a substituted or unsubstituted C₂-C₆₀ alkynylene group, a substituted or unsubstituted C₃-C₁₀ cycloalkylene group, a substituted or unsubstituted C₃-C₁₀ heterocycloalkenylene group, a substituted or unsubstituted C₃-C₁₀ cycloalkenylene group, or a substituted or unsubstituted C₁-C₁₀ heterocycloalkenylene group, or *—O—*′, where * and *′ are bonding sites with adjacent atoms,

Z1 to Z4 each independently represent hydrogen, deuterium, —F, —Cl, —Br, —I, a hydroxyl group, a cyano group, a nitro group, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₆₀ carbocyclic group, a substituted or unsubstituted C₁-C₆₀ heterocyclic group, a substituted or unsubstituted C₆-C₆₀ aryloxy group, or a substituted or unsubstituted C₆-C₆₀ arylthio group, and the n1, n2, n3, and n4 each independently represent an integer from 0 to 5. In the aforementioned Chemical Formula 4, M represents Zn, Ti, Zr, Sn, W, Ta, Ni, Mo, Cu, or V, and p and q in the aforementioned Chemical Formula 4 independently represent one of the integers 1 to 5.

In an embodiment, the molecular weight of the first compound may be 140 g/mol or more.

In an embodiment, the ratio of a number of oxygen to the total number of carbon atoms and oxygen atoms included in the first compound may be 0.3 or more.

In an embodiment, the first compound may include at least one of a secondary alcohol and a tertiary alcohol.

In an embodiment, the first compound may include at least one of Compounds 1 to 3 below.

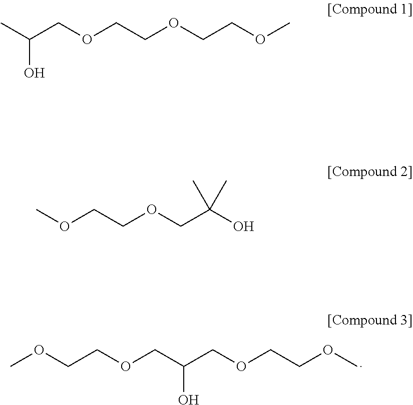

In an embodiment, the second compound may be a zinc-containing oxide.

In an embodiment, the second compound may be represented by the following Chemical Formula 4-1:

Zn₍₁₋ᵣ₎M′ᵣO [Chemical Formula 4-1],

where, in Chemical Formula 4-1, M′ is Mg, Co, Ni, Zr, Mn, Sn, Y, Al, or any combinations thereof, and r in Chemical Formula 4-1 is a number greater than 0 and equal to or less than 0.5.

In an embodiment, the second compound may include at least one of ZnO, ZnMgO, ZnAIO, ZnSiO, ZnYbO, TiO₂, WO₃, W₂O₃, and WO₂.

By embodiments, the luminous efficiency and reliability of the light-emitting element may be improved.

### BRIEF DESCRIPTION OF THE DRAWINGS

The above and other exemplary embodiments, advantages and features of this disclosure will become more apparent by describing in further detail exemplary embodiments thereof with reference to the accompanying drawings, in which:

FIG. 1 is a schematic cross-sectional view of an embodiment of a display device.

FIG. 2 is a schematic diagram of an embodiment of quantum dots.

FIG. 3 is a cross-sectional view of an embodiment of a manufacturing process of a light-emitting element.

FIG. 4 is an enlarged view of an embodiment of the surface of quantum dots.

FIG. 5 is a graph showing the probability of ligand penetration according to the molecular weight of the solvent.

FIG. 6 is a graph showing the surface reaction probability according to solvent type.

FIG. 7 is a graph of the surface influence probability (Ps) of the shell of quantum dots predicted through molecular dynamics simulation.

FIG. 8 is a graph of luminescence intensity measurement according to solvent.

### DETAILED DESCRIPTION

Hereinafter, with reference to the attached drawings, various embodiments of the invention will be described in detail so that those skilled in the art may easily implement the invention. Embodiments of the disclosure may be implemented in many different forms and is not limited to the embodiments described herein.

In order to clearly explain the invention, parts that are not relevant to the description are omitted, and identical or similar components are assigned the same reference numerals throughout the specification.

In addition, the size and thickness of each component shown in the drawings are arbitrarily shown for convenience of explanation, so the invention is not necessarily limited to that which is shown. In the drawings, thicknesses are enlarged to clearly express various layers and areas. And in the drawings, for convenience of explanation, the thicknesses of some layers and regions are exaggerated.

Additionally, when a part of a layer, membrane, region, or plate is said to be “above” or “on” another part, this includes not only cases where it is “directly above” another part, but also cases where there is another part in between. In contrast, when an element is referred to as being “directly on” another element, there are no intervening elements present. In addition, being “above” or “on” a reference portion means being disposed above or below the reference portion, and does not necessarily mean being disposed “above” or “on” it in the direction opposite to gravity.

In addition, throughout the specification, when a part is said to “include” a certain element, this means that it may further include other elements, rather than excluding other elements, unless specifically stated to the contrary.

In addition, throughout the specification, when reference is made to “in a plan view,” this means when the target portion is viewed from above, and when reference is made to “in a cross-section,” this means when a cross-section of the target portion is cut vertically and viewed from the side.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). The term “about” can mean within one or more standard deviations, or within ±30%, 20%, 10%, 5% of the stated value, for example.

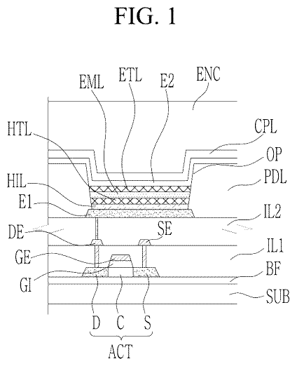

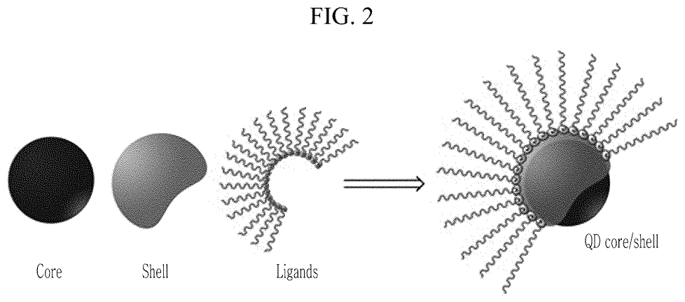

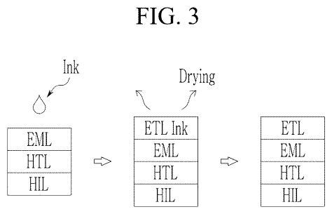

First, a display device in an embodiment will be looked at with reference to FIGS. 1 to 3. FIG. 1 is a cross-sectional view of an embodiment of a display device, FIG. 2 is a schematic diagram of an embodiment of quantum dots, and FIG. 3 is a cross-sectional view of an embodiment of a manufacturing process of a light-emitting element.

A display device in an embodiment includes a substrate SUB. The substrate SUB may include a flexible material such as plastic that may bend, fold, or roll, or may include a rigid substrate.

A buffer layer BF may be disposed on the substrate SUB. Depending on the embodiment, the buffer layer BF may be omitted. The buffer layer BF may include silicon nitride SiNₓ, silicon oxide SiO₂, or silicon oxynitride. The buffer layer BF is disposed between the substrate SUB and the semiconductor layer ACT, and improves the characteristics of the polycrystalline silicon by blocking impurities from the substrate SUB during the crystallization process to form polycrystalline silicon, and by flattening, the stress of the semiconductor layer ACT formed on the buffer layer BF may be alleviated. A semiconductor layer ACT is disposed on the buffer layer BF. The semiconductor layer ACT may include or consist of polycrystalline silicon or an oxide semiconductor. The semiconductor layer ACT includes a channel region C, a source region S, and a drain region D. The source region S and drain region D are respectively disposed on opposite sides of the channel region C. The channel region C is an intrinsic semiconductor that is not doped with impurities, and the source region S and drain region D are impurity semiconductors that are doped with conductive impurities. The semiconductor layer ACT may include or consist of an oxide semiconductor, in which case a protective layer may be added to protect the oxide semiconductor material, which is vulnerable to external environments such as relatively high temperature.

A gate insulating layer GI is disposed on the semiconductor layer ACT. The gate insulating layer GI may be a single layer or a multilayer including or consisting of at least one of silicon nitride SiNₓ, silicon oxide SiO₂, and silicon oxynitride.

A gate electrode GE is disposed on the gate insulating layer GI, the gate electrode GE includes any one of copper (Cu), a copper alloy, aluminum (Al), an aluminum alloy, molybdenum (Mo), and a molybdenum alloy, and it may be a single-layer or a multi-layer in which metal layers are stacked.

An inter-insulating layer IL1 is disposed on the gate electrode GE and the gate insulating layer GI. The inter-insulating layer IL1 may include silicon nitride SiNₓ, silicon oxide SiO₂, or silicon oxynitride. Openings exposing the source region S and the drain region D are disposed in the inter-insulating layer IL1.

A source electrode SE and a drain electrode DE are disposed on the inter-insulating layer IL1. The source electrode SE and the drain electrode DE are electrically connected to the source region S and the drain region D of the semiconductor layer ACT through openings defined in the inter-insulating layer IL1, respectively.

A protective layer IL2 is disposed on the inter-insulating layer IL1, the source electrode SE, and the drain electrode DE. The protective layer IL2 covers and flattens the inter-insulating layer IL1, the source electrode SE, and the drain electrode DE, so that the first electrode E1 may be formed on the protective layer IL2 without steps. This protective layer IL2 may include or consist of an organic material such as polyacrylate resin or polyimide resin, or a laminated film of an organic material and an inorganic material.

The first electrode E1 is disposed on the protective layer IL2. The first electrode E1 is electrically connected to the drain electrode DE through an opening in the protective layer IL2.

The first electrode E1 may be formed, e.g., by providing the first electrode material using a deposition method or sputtering method. When the first electrode E1 is an anode, a relatively high work function material that facilitates hole injection may be used as the first electrode material. The first electrode E1 may be a reflective electrode, a transflective electrode, or a transmissive electrode. In order to form the first electrode E1, which is a transparent electrode, materials for the first electrode such as indium tin oxide (ITO), indium zinc oxide (IZO), tin oxide (SnO₂), zinc oxide (ZnO), or any combinations thereof may be used.

In an alternative embodiment, in order to form the first electrode E1, which is a transfiective electrode or a reflective electrode, magnesium (Mg), silver (Ag), aluminum (Al), or aluminum-lithium (Al—Li) may be used as the first electrode material, or calcium (Ca), magnesium-indium (Mg—In ), magnesium-silver (Mg—Ag), or any combinations thereof may be used.

The first electrode E1 may have a single-layer structure (consist of a single layer) or a multi-layer structure including a plurality of layers. In an embodiment, the first electrode E1 may have a three-layer structure of ITO/Ag/ITO, for example.

A driving transistor including a gate electrode GE, a semiconductor layer ACT, a source electrode SE, and a drain electrode DE is connected to the first electrode E1 and supplies a driving current to each light-emitting element ED. In addition to the driving transistor shown in FIG. 1, the display device in the illustrated embodiment includes a switching transistor (not shown) connected to a data line and transmitting a data voltage in response to a scan signal, and a switching transistor (not shown) connected to the driving transistor and driven in response to the scan signal, and it may further include a compensation transistor (not shown) that compensates the threshold voltage of the transistor.

A partition PDL is disposed on the protective layer IL2 and the first electrode E1. The partition PDL may define a pixel opening OP that overlaps the first electrode E1 and defines a light-emitting area. The partition PDL may include or consist of an organic material such as polyacrylate resin or polyimide resin, or a silica-based inorganic material. The pixel opening OP may have a planar shape substantially similar to that of the first electrode E1, and may have a diamond or octagonal shape similar to a diamond in a plan view, but is not limited thereto and may have any shape such as a square or polygon.

The light-emitting element ED includes the first electrode E1, a hole injection layer HIL, the hole transport layer HTL, an emission layer EML, the electron transport layer ETL, and a second electrode E2.

Each hole injection layer HIL may include a hole injection material. Hole injection materials may include, e.g., phthalocyanine compounds such as copper phthalocyanine; DNTPD (N,N′-diphenyl-N,N′-bis-[4-(phenyl-m-tolyl-amino)-phenyl]-biphenyl-4,4′-diamine), m-MTDATA (4,4′,4″-[tris(3-methylphenyl)phenylamino]triphenylamine), TDATA (4,4′4″-tris(N,N-diphenylamino)triphenylamine), 2-TNATA (4,4′,4″-tris{N,-(2-naphthyl)-N-phenylamino}-triphenylamine), PEDOT/PSS (poly(3,4-ethylenedioxythiophene)/poly(4-styrenesulfonate)), PANI/DBSA (polyaniline/dodecylbenzenesulfonic acid), PANI/CSA (polyaniline/camphor sulfonic acid), PANI/PSS (polyaniline/poly(4-styrenesulfonate)), NPB(N,N′-di(naphthalene-1-yl)-N,N′-diphenyl-benzidine), NPD (N,N′-di(1-naphthyl)-N,N′-diphenyl-(1,1′-biphenyl)-4,4′-diamine), triphenylamine-containing polyetherketone (TPAPEK), 4-Isopropyl-4′-methyldiphenyliodonium [tetrakis(pentafluorophenyl)borate], HAT-CN (dipyrazino[2,3-f: 2′,3′-h]quinoxaline-2,3,6,7,1 0,11-hexacarbonitrile), and others.

The hole transport layer HTL may be disposed on the hole injection layer HIL. Each hole transport layer HTL may include a hole transport material. Hole transport materials include, e.g., carbazole-based derivatives such as N-phenylcarbazole and polyvinylcarbazole, fluorene-based derivatives, and TPD (N,N′-bis(3-methylphenyl)-N,N′-diphenyl), triphenylamine derivatives such as -[1,1-biphenyl]-4,4′-diamine), TCTA (4,4′,4″-tris(N-carbazolyl)triphenylamine), NPB(N,N′-di(naphthalene-1-yl)-N,N′-diphenyl-benzidine), TAPC(4,4′-cyclohexylidene bis[N,N-bis(4-methylphenyl)benzenamine]), HMTPD(4,4′-bis[N,N′-(3-tolyl)amino]-3,3′-dimethylbiphenyl), mCP(1,3-bis(N-carbazolyl)benzene), CzSi(9-(4-tert-butylphenyl)), 3,6-bis(triphenylsilyl)-9H-carbazole), m-MTDATA (4,4′,4″-[tris(3-methylphenyl)phenylamino]triphenylamine), etc.

The light-emitting layer EML may emit red light or green light. The light-emitting layer EML in an embodiment may include quantum dots as shown in FIG. 2. Now, quantum dots will be described in detail below.

In this specification, quantum dots (hereinafter also referred to as semiconductor nanocrystals) include group II-VI compounds, group Ill-V compounds, group IV-VI compounds, group IV elements or compounds, group I-Ill-VI compounds, and, it may include a group II-Ill-VI compound, a group 1-II-IV-VI compound, or any combinations thereof.

The II-VI group compounds include binary compounds including at least one of CdSe, CdTe, ZnS, ZnSe, ZnTe, ZnO, HgS, HgSe, HgTe, MgSe, MgS, and any combinations thereof; a tri-element compound selected from AgInS, CuInS, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and any combinations thereof; and a tetraelement compound selected from the group including HgZnTeS, CdZnSeS, CdZnSeTe, CdZnSTe, CdHgSeS, CdHgSeTe, CdHgSTe, HgZnSeS, HgZnSeTe, HgZnSTe, and any combinations thereof. The group II-VI compound may further include a Group III metal.

The group III-V compounds may include binary compounds such as GaN, GaP, GaAs, GaSb, AlN, AIP, AIAs, AISb, InN, InP, InAs, InSb, or any combinations thereof; ternary compounds including at least one of GaNP, GaNAs, GaNSb, GaPAs, GaPSb, AlNP, AlNAs, AlNSb, AIPAs, AIPSb, InGaP, InNP, InNAs, InNSb, InPAs, InZnP, InPSb, or any combinations thereof; and quaternary compounds including at least one of GaAINP, GaAINAs, GaAINSb, GaAIPAs, GaAIPSb, GaInNP, GaInNAs, GalnNSb, GaInPAs, GalnPSb, InAINP, InAINAs, InAINSb, InAIPAs, InAIPSb, InZnP, and any combinations thereof. The group III-V compound may further include a group II metal (e.g., InZnP).

The IV-VI group compounds include binary compounds including at least one of SnS, SnSe, SnTe, PbS, PbSe, PbTe, and any combinations thereof, a ternary compound including at lest one of SnSeS, SnSeTe, SnSTe, PbSeS, PbSeTe, PbSTe, SnPbS, SnPbSe, SnPbTe, and any combinations thereof; and a quaternary element compound including at least one of SnPbSSe, SnPbSeTe, SnPbSTe, and any combinations thereof.

The group IV element or compound is a monoelement compound including at least one of Si, Ge, and any combinations thereof; and a binary compound including at least one of SiC, SiGe, and any combinations thereof, but is not limited thereto.

In embodiments, the Group 1-Ill-VI compounds include, but are not limited to, CulnSe₂, CulnS₂, CuInGaSe, and CuInGaS. In embodiments, the Group 1-11-IV-VI compounds include, but are not limited to, CuZnSnSe and CuZnSnS. The Group IV element or compound is a single element including at least one of Si, Ge, and any combinations thereof; and a binary compound including at least one of SiC, SiGe, and any combinations thereof.

The group II-III-VI compounds include ZnGaS, ZnAIS, ZnInS, ZnGaSe, ZnAISe, ZnlnSe, ZnGaTe, ZnAITe, ZnlnTe, ZnGaO, ZnAIO, ZnlnO, HgGaS, HgAIS, HgInS, HgGaSe, HgAISe, HglnSe, HgGaTe, HgAITe, and may include or consist of at least one of HglnTe, MgGaS, MgAIS, MgInS, MgGaSe, MgAISe, MglnSe, and any combinations thereof, but is not limited thereto.

The group I-II-IV-VI compound may include or consist of CuZnSnSe and CuZnSnS, but is not limited thereto.

In an embodiment, the quantum dots may not include cadmium. Quantum dots may include semiconductor nanocrystals based on group Ill-V compounds including indium and phosphorus. The group III-V compound may further include zinc.

Quantum dots may include semiconductor nanocrystals based on group II-VI compounds including chalcogen elements (e.g., sulfur, selenium, tellurium, or any combinations thereof) and zinc.

In quantum dots, the above-mentioned di-element compound, tri-element compound and/or quaternary compound may exist in the particle at a uniform concentration, or may exist in the same particle with a concentration distribution partially divided into different states. Additionally, one quantum dot may have a core/shell structure surrounding other quantum dots. The interface between the core and the shell may have a concentration gradient in which the concentration of elements present in the shell decreases toward the center.

In some embodiments, quantum dots may have a core-shell structure including a core including the above-described nanocrystals and a shell surrounding the core, as shown in FIG. 2. The shell of the quantum dot may serve as a protective layer to maintain semiconductor properties by preventing chemical denaturation of the core and/or as a charging layer to impart electrophoretic properties to the quantum dot. The shell may be single or multi-layered. The interface between the core and the shell may have a concentration gradient in which the concentration of elements present in the shell decreases toward the center. In embodiments, the shell of the quantum dot include metal or non-metal oxides, semiconductor compounds, or any combinations thereof.

In an embodiment, the oxide of the metal or non-metal is a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄, NiO, or MgAl₂O₄, CoFe₂O₄, NiFe₂O₄, CoMn₂O₄, etc., for example, but the invention is not limited thereto.

In addition, the semiconductor compounds include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AIAs, AIP, AISb, etc. However, the invention is not limited thereto.

The interface between the core and the shell may have a concentration gradient in which the concentration of elements present in the shell decreases toward the center. Additionally, the semiconductor nanocrystal may have a structure including a single semiconductor nanocrystal core and a multi-layered shell surrounding it. In an embodiment, the multilayer shell may have two or more layers, such as 2, 3, 4, 5, or more layers. The two adjacent layers of the shell may have a single composition or different compositions. In a multilayer shell, each layer may have a composition that changes along the radius.

Quantum dots may have a full width of half maximum (FWHM) of the emission wavelength spectrum of about 45 nanometers (nm) or less, preferably about 40 nm or less, more preferably about 30 nm or less, and within this range, color purity or color reproducibility may be improved. Additionally, since the light emitted through these quantum dots is emitted in all directions, the optical viewing angle may be improved.

The quantum dots may have different energy band gaps between the shell material and the core material. In an embodiment, the energy band gap of the shell material may be larger than that of the core material, for example. In other embodiments, the energy band gap of the shell material may be smaller than that of the core material. The quantum dots may have a multi-layered shell.

In a multilayer shell, the energy band gap of the outer layer may be larger than that of the inner layer (i.e., the layer close to the core). In a multilayer shell, the energy band gap of the outer layer may be smaller than that of the inner layer.

Quantum dots may control absorption/emission wavelengths by adjusting their composition and size. The maximum emission peak wavelength of the quantum dot may range from ultraviolet to infrared wavelengths or longer.

Quantum dots may have a quantum efficiency of at least about 10%, such as at least about 30%, at least about 50%, at least about 60%, at least about 70%, at least about 90%, or even at least 100%. Quantum dots may have a relatively narrow spectrum. The quantum dots may have a full width at half maximum of the emission wavelength spectrum of about 50 nm or less, such as about 45 nm or less, about 40 nm or less, or about 30 nm or less, for example. The quantum dots may have a particle size of about 1 nm or more and about 100 nm or less. The size of a particle refers to the diameter of the particle or the diameter converted by assuming a spherical shape from a two-dimensional image obtained by transmission electron microscopy analysis. The quantum dots may be about 1 nm to about 20 nm, such as at least 2 nm, at least 3 nm, or at least 4 nm and at most 50 nm, at most 40 nm, at most 30 nm, at most 20 nm, at most 15 nm, such as at least 10 nm, and it may have a size of nm or less. The shape of the quantum dot is not particularly limited. In an embodiment, the shape of the quantum dot may include, but is not limited to, a sphere, a polyhedron, a pyramid, a multipod, a square, a cuboid, a nanotube, a nanorod, a nanowire, a nanosheet, or any combinations thereof, for example.

Quantum dots are commercially available or may be appropriately synthesized. The particle size of quantum dots may be controlled relatively freely during colloid synthesis, and the particle size may also be adjusted uniformly.

Quantum dots may include organic ligands (e.g., having hydrophobic moieties and/or hydrophilic moieties) as shown in FIG. 2. The organic ligand residue may be bound to the surface of the quantum dot. The organic ligand includes RCOOH, RNH₂, R₂NH, R₃N, RSH, R₃PO, R₃P, ROH, RCOOR, RPO(OH)₂, RHPOOH, R₂POOH, or any combinations thereof, where each R is independently C₃ to a substituted or unsubstituted alkyl of C40 (e.g., C5 or more and C24 or less), a substituted or unsubstituted alkenyl, a substituted or unsubstituted aliphatic hydrocarbon group of C₃ to C40, a substituted or unsubstituted aryl group of C6 to C40, a substituted or unsubstituted aromatic hydrocarbon group of C6 to C40 (e.g., C6 or more and C20 or less), or any combinations thereof. The organic ligand in an embodiment may exhibit nonpolarity.

In embodiments, the aforementioned organic ligands include thiol compounds such as methane thiol, ethane thiol, propane thiol, butane thiol, pentane thiol, hexane thiol, octane thiol, dodecane thiol, hexadecane thiol, octadecane thiol, benzyl thiol; amines such as methane amine, ethane amine, propane amine, butane amine, pentyl amine, hexyl amine, octyl amine, nonylamine, decylamine, dodecylamine, hexadecylamine, octadecylamine, dimethylamine, diethylamine, dipropylamine, tributylamine, trioctylamine; carboxylic acid compounds such as methanoic acid, ethanoic acid, propanoic acid, butanoic acid, pentanoic acid, hexanoic acid, heptanoic acid, octanoic acid, dodecanoic acid, hexadecanoic acid, octadecanoic acid, oleic acid, benzoic acid; phosphine compounds such as methyl phosphine, ethyl phosphine, propyl phosphine, butyl phosphine, pentyl phosphine, octylphosphine, dioctyl phosphine, tributylphosphine, trioctylphosphine; phosphine compounds or their oxide compounds such as methyl phosphine oxide, ethyl phosphine oxide, propyl phosphine oxide, butyl phosphine oxide, pentyl phosphine oxide, tributylphosphine oxide, octylphosphine oxide, dioctyl phosphine oxide, trioctylphosphine oxide; diphenyl phosphine, triphenyl phosphine compounds or their oxide compounds; hexylphosphinic acid, octylphosphinic acid, dodecylphosphinic acid, tetradecylphosphinic acid, hexadecylphosphinic acid, octadecylphosphinic acid and other C5 to C20 alkyl phosphinic acids, C5 to C20 alkyl phosphonic acids, etc., but are not limited to these. Quantum dots may include hydrophobic organic ligands alone or in a combination of one or more types. The hydrophobic organic ligand may not include or consist of a photopolymerizable residue (e.g., an acrylate group, a methacrylate group, etc.).

The electron transport layer ETL may be disposed on the light-emitting layer EML.

As shown in FIG. 3, the electron transport layer ETL may be formed by dripping ink including or consisting of a solvent and a metal oxide onto the emitting layer EML and performing a drying process.

At this time, the solvent may penetrate into the light-emitting layer EML.

The solvent may remain on the top of the light-emitting layer EML or at least a portion of the inside of the light-emitting layer EML before performing the drying process. The solvent may diffuse into the light-emitting layer EML and have a chemical effect on the shell of the quantum dots. As the thickness of the quantum dot shell decreases, the photoluminescence intensity of the quantum dot may decrease, thereby reducing the efficiency of the light-emitting element. The light-emitting element in an embodiment uses a solvent that has minimal effect on quantum dots, thereby preventing a decrease in efficiency of the light-emitting element.

The electron transport layer ETL in an embodiment may include a metal oxide composition. The metal oxide composition may include a solvent and a metal oxide. At least a portion of the solvent may remain in the electron transport layer ETL even when the drying process is performed.

The solvent may include a first compound represented by Chemical Formulas 1 to 3 below, and the metal oxide may include a second compound represented by Chemical Formula 4 below.

The first compound in an embodiment may include an aliphatic chain having a molecular weight of 140 grams per (g/mol) or more. When the molecular weight of the first compound satisfies the above numerical range, the probability of penetration between the ligands bound to the surface of the quantum dot may decrease.

Additionally, in the first compound, the ratio of the number of oxygen atoms to the total number of carbon atoms and oxygen atoms may be 0.3 or more.

When the number of oxygen atoms in the first compound increases, the polarity of the first compound may increase. Since the ligand in an embodiment is nonpolar, in the case of a highly polar first compound, the permeability to the ligand may be low.

Additionally, the first compound in an embodiment may include a secondary alcohol and/or a tertiary alcohol. Additionally, the first compound may include at least one ether group. The first compound may ensure the dispersibility of the second compound by including or consisting of a secondary or tertiary alcohol and an ether group. The solvent that penetrates close to the surface of the quantum dot reacts with the shell of the quantum dot. In this case, when the first compound includes or consists of a secondary or tertiary alcohol, the reactivity of the quantum dot and the solvent may be lowered. When the first compound includes or consists of a primary alcohol, there are no bulky atoms around the hydroxy group that react with the surface of the quantum dot, so a chemical reaction between the solvent and the surface of the quantum dot may occur relatively easily. However, when the first compound includes or consists of a secondary or tertiary alcohol, relatively bulky alkyl groups are disposed around the hydroxyl group of the solvent, and thus the chemical reaction between the solvent and the surface of the quantum dots may be suppressed.

A light-emitting element in an embodiment may include a first compound that satisfies the above-described characteristics. The first compound may include at least one of the following Chemical Formulas 1 to 3:

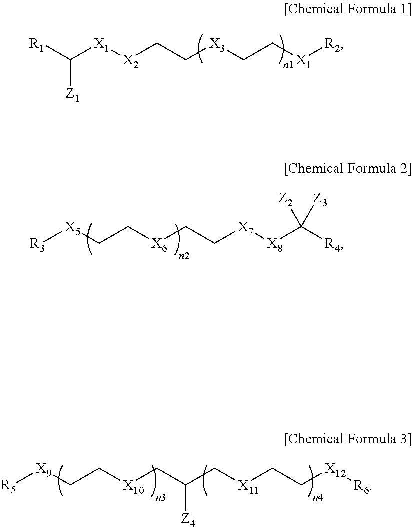

In Chemical Formulas 1 to 3, R₁, R₂, R₃, R₄, R₅, and R₆ may each independently be deuterium, a hydroxyl group, a C₁-C₂₀ alkyl group, a C₁-C₂₀ alkoxy group, a C₃-C₃₀ carbocyclic group, a C₁-C₃₀ heterocyclic group, a C₆-C₃₀ aryloxy group, a C₆-C₃₀ arylthio group, or a substituted or unsubstituted C₁-C₂₀ alkyl group or C₁-C₂₀ alkoxy group with any combinations of deuterium, the hydroxyl group, the C₁-C₂₀ alkyl group, the C₁-C₂₀ alkoxy group, the C₃-C₃₀ carbocyclic group, the C₁-C₃₀ heterocyclic group, the C₆-C₃₀ aryloxy group and the C₆-C₃₀ arylthio group, and X₁ to X₁₂ may each independently be a single bond, a substituted or unsubstituted C₁-C₆₀ alkylene group, a substituted or unsubstituted C₂-C₆₀ alkenylene group, a substituted or unsubstituted C₂-C₆₀ alkynylene group, a substituted or unsubstituted C₃-C₁₀ cycloalkylene group, a substituted or unsubstituted C₃-C₁₀ heterocycloalkenylene group, a substituted or unsubstituted C₁-C₁₀ heterocycloalkenylene group, or *—O—*′. The above * and *′ may be a bonding site with neighboring atoms, and Z1 to Z4 may each independently be hydrogen, deuterium, —F, —Cl, —Br, —I, a hydroxyl group, a cyano group, a nitro group, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₆₀ carbocyclic group, a substituted or unsubstituted C₁-C₆₀ heterocyclic group, a substituted or unsubstituted C₆-C₆₀ aryloxy group, or a substituted or unsubstituted C₆-C₆₀ arylthio group, and the above n₁, n₂, n₃, and n₄ may each independently be an integer from 0 to 5.

In an embodiment, the first compound may include at least one of the following Compounds 1 to 28:

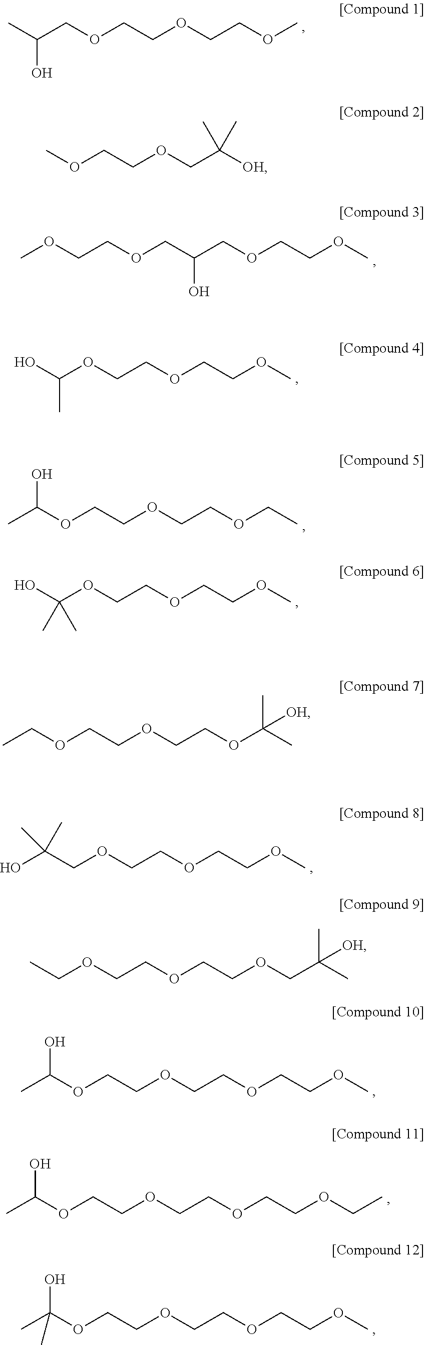

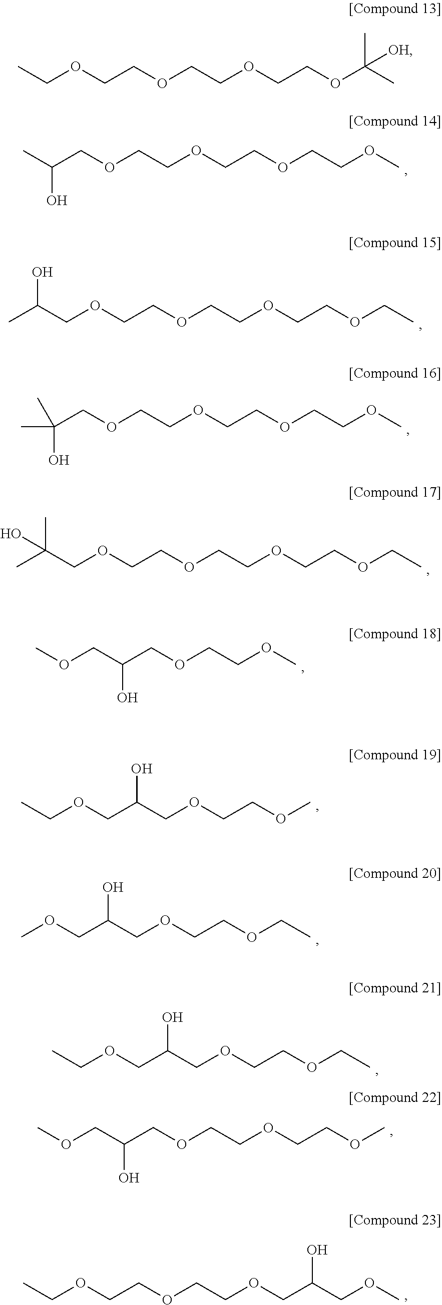

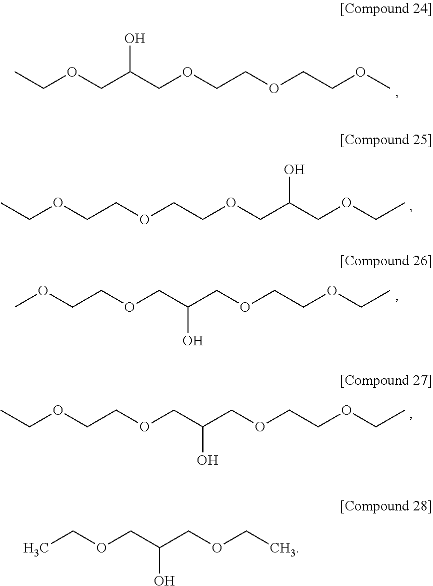

Among the Compounds 1 to 28, Compounds 1 to 3 will be examined in more detail. Referencing Table 1 below and examining Compounds 1 to 3, it may be seen that by having relatively large molecular weights, the probability of the solvent penetrating between the ligands may be reduced. Additionally, the f_{O} value may be 0.3 or more, and Compounds 1 to 3 having this value may have a predetermined polarity, so permeability to non-polar ligands may be reduced. The f₀ is a quantitative parameter for polarity and is defined as the ratio of the number of oxygen atoms to the total carbon and oxygen atoms. Additionally, since the carbon to which OH is bonded is secondary or tertiary, even when the solvent reaches the surface of the shell, it may be difficult to chemically react with the shell.

TABLE 1

| | | | molecular | fₒ | OH |
|---|---|---|---|---|---|
| acronym | molecule name | molecule structure | weight | value | order |
| compound 1 | 1-[2-(2- Methoxyethoxy) ethoxy] propan-2-ol | 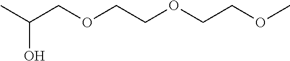 | 178.2 | 0.33 | secondary |
| compound 2 | 1-(2- Methoxyethoxy)- 2-methyl-2- propanol | 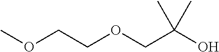 | 148.2 | 0.30 | tertiary |
| compound 3 | 1,3-bis(2- methoxyethoxy) propan-2- ol | 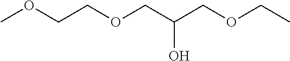 | 208.3 | 0.36 | secondary |

In an embodiment, the second compound may be represented by Chemical Formula 4 below:

MₚO_{q} [Chemical Formula 4].

In Chemical Formula 4, M may be Zn, Ti, Zr, Sn, W, Ta, Ni, Mo, Cu, or V.

In Chemical Formula 4, p and q may independently be one of the integers of 1 to 5. In an embodiment, M may be Zn, for example. In an embodiment, M may be Zn, and p and q may each be 1, for example. In an embodiment, the second compound may be a zinc-containing oxide.

In an embodiment, the second compound may be ZnO, ZnMgO, ZnAIO, ZnSiO, ZnYbO, TiO₂, WO₃, W₂O₃, and WO₂, or any combinations thereof.

In an embodiment, the second compound may be represented by the following Chemical Formula 4-1:

Zn₍₁₋ᵣ₎M′ᵣO [Chemical Formula 4-1],

where M′ in Chemical Formula 4-1 may be Mg, Co, Ni, Zr, Mn, Sn, Y, Al, or any combinations thereof. In Chemical Formula 4-1 r may be a number greater than 0 and equal to or less than 0.5.

The metal oxide composition in the embodiment may include a solvent including or consisting of the first compound and a metal oxide including or consisting of the second compound. At this time, the aforementioned solvent may have characteristics of relatively high molecular weight and polarity, and includes a secondary or tertiary alcohol, which may reduce the probability of surface reactions between the solvent and quantum dots, and the probability that the solvent will penetrate ligands bound to the quantum dot surface. According to this, the chemical reaction between the solvent and the quantum dots may be reduced, ensuring the reliability of the quantum dots, and improving the photoluminescence intensity of the light-emitting element.

The second electrode E2 may be disposed on the electron transport layer ETL. The second electrode E2 may be a cathode, which is an electron injection electrode. In this case, the material for the second electrode E2 may be a metal with a relatively low work function, an alloy, an electrically conductive compound, or any combinations thereof.

The second electrode E2 is lithium (Li), silver (Ag), magnesium (Mg), aluminum (Al), aluminum-lithium (Al—Li), calcium (Ca), magnesium-indium (Mg—In), magnesium-silver (Mg—Ag), ytterbium (Yb), silver-ytterbium (Ag—Yb), ITO, IZO, or any combinations thereof. The second electrode E2 may be a transmissive electrode, a semi-transmissive electrode, or a reflective electrode.

The second electrode E2 may have a single-layer structure or a multi-layer structure having a plurality of layers.

Here, the first electrode E1 may be an anode, which is a hole injection electrode, and the second electrode E2 may be a cathode, which is an electron injection electrode. However, the embodiment is not necessarily limited to this, and the first electrode E1 may be a cathode and the second electrode E2 may be an anode depending on the driving method of the display device.

A capping layer CPL may be disposed on the second electrode E2. The capping layer CPL may play a role in improving external light emission efficiency based on the principle of constructive interference. The capping layer CPL may be an organic capping layer including an organic material, an inorganic capping layer including an inorganic material, or an organic-inorganic composite capping layer including an organic material and an inorganic material.

An encapsulation layer ENC may be disposed on the capping layer CPL.

The encapsulation layer ENC may seal the display layer by covering not only the top surface but also the side surfaces of the display layer including the light-emitting element ED.

Since the light-emitting element is substantially vulnerable to moisture and oxygen, the encapsulation layer ENC seals the display layer and blocks the inflow of external moisture and oxygen. The encapsulation layer ENC may include a plurality of layers, and may be formed as a composite film including both an inorganic film and an organic film, and may be a triple layer in which a first inorganic film, an organic film, and a second inorganic film are formed sequentially.

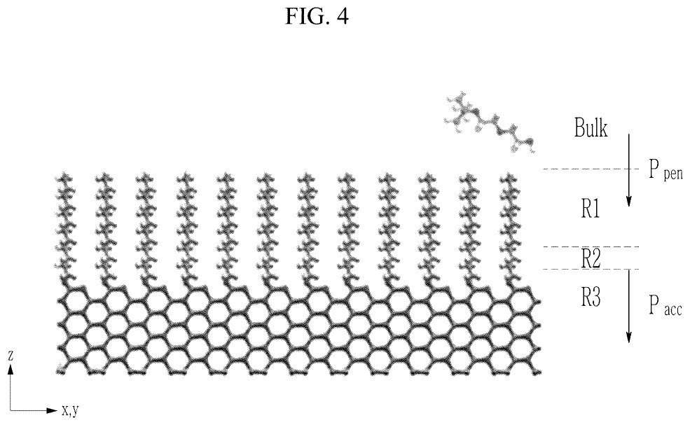

Hereinafter, a compound in an embodiment will be described in more detail with reference to FIGS. 4 to 8.

FIG. 4 is a diagram of the probability of ligand penetration (Ppen) and surface reaction probability (Pacc) of the solvent calculated using molecular dynamics simulation. That is, referring to FIG. 4, the reaction probability of solvents on the surface (e.g., R1, R2 or R3) of the quantum dot is calculated using molecular dynamics simulation, and in particular, the probability of ligand penetration that must pass through to reach the shell (e.g., ZnS) surface R3 is calculated.

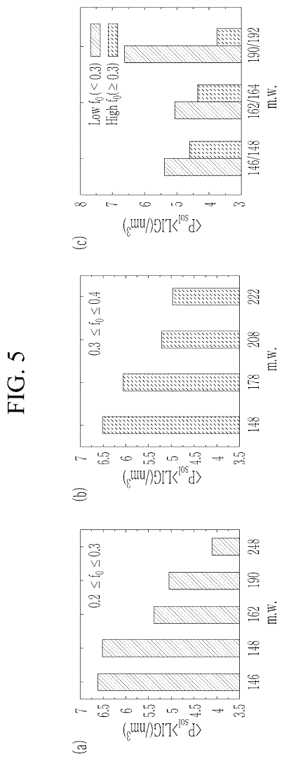

FIG. 5 is a graph showing the probability of ligand penetration (Pₛₒₗ) according to the molecular weight (m.w) of the solvent. In FIG. 5, (a) is a result derived through a solvent according to a comparative example, (b) is a result derived through a solvent in an embodiment, and (c) is a graph comparing some of (a) and (b).

Referring to (a) of FIG. 5, the ligand penetration probability is shown for cases where the f₀ is 0.2 to 0.3 and the molecular weight is 146, 148, 162, 190, and 248, depending on the comparative example. As the molecular weight of the solvent increases, it may be seen that the probability of the ligand penetrating and reaching the surface of the quantum dot decreases.

Referring to (b) of FIG. 5, depending on the embodiment, the ligand penetration probability is for cases where the f₀ is 0.3 or more and 0.4 or less and the molecular weight is 148, 178, 208, or 222. In the case of the example, as the molecular weight of the solvent increases, the probability that the solvent penetrates the ligand and reaches the surface of the quantum dot may decrease.

In particular, referring to (c) of FIG. 5, it was confirmed that in the case of a relatively high polarity example with a similar molecular weight, the probability (Pₛₒₗ) of the solvent according to the example penetrating the ligand and reaching the surface of the quantum dot was lowered compared to the comparative example.

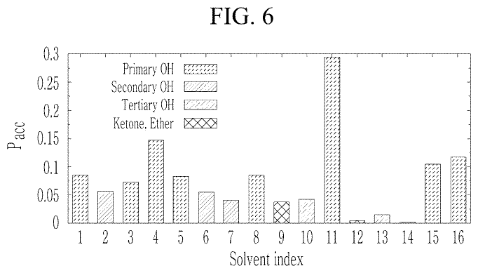

Next, FIG. 6 is a graph showing the surface reaction probability depending on the type of solvent. Referring to FIG. 6, it was confirmed that solvents No. 7 corresponding to Compound 1, No. 13 corresponding to Compound 2, and No. 14 corresponding to Compound 3 show a relatively low surface reaction probability (Pacc). In particular, in the case of comparative examples including or consisting of a primary alcohol, the probability of surface reaction was found to be significantly higher than 0.05. Additionally, even when including or consisting of an ether group, the probability of surface reaction was significantly low.

For reference, the solvents corresponding to each number in FIG. 6 are as shown in Table 2, where numbers 7, 13, and 14 are implementation embodiments of the invention, and the remaining solvents correspond to comparative examples.

TABLE 2

| Index | molecule name | molecule structure |
|---|---|---|
| 1 | Diethylenglycol-mono-tert-butyl ether | 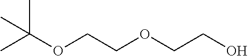 |
| 2 | Tripropylene glycol monobutyl ether | 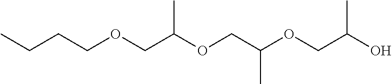 [SMILES: CCCCOCC(C)OCC(C)OCC(C)O] |
| 3 | Triethylene glycol monoisopropyl ether | 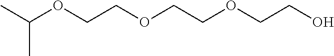 |
| 4 | Triethylene glycol monomethyl ether | 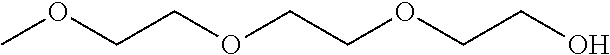 |
| 5 | Diethylene glycol monohexyl ether | 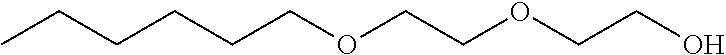 |
| 6 | Glycerol α,α′-diethyl ether | 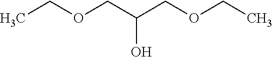 |
| 7 | 1-[2-(2-Methoxyethoxy)ethoxy]propan-2-ol | 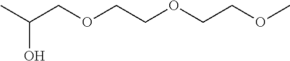 |
| 8 | Octylene glycol | 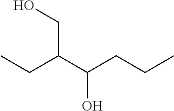 |
| 9 | Propylene carbonate | 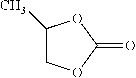 |
| 10 | 2-Methyl-2,4-pentanediol | 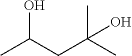 |
| 11 | Diethylene glycol | 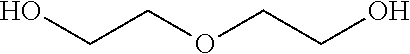 |
| 12 | Tetraethylene glycol dimethyl ether | 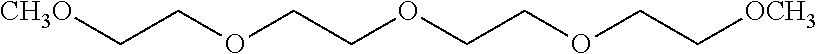 |
| 13 | 1-(2-Methoxyethoxy)-2-methyl-2-propanol | 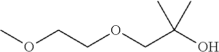 |
| 14 | 1,3-Bis(2-methoxyethoxy)propan-2-ol | 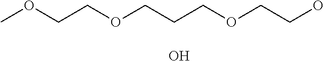 |
| 15 | Diethylene glycol monobutyl ether | 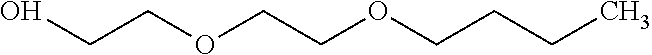 |
| 16 | 1-Nonanol | 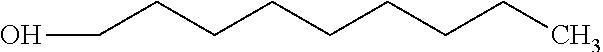 |

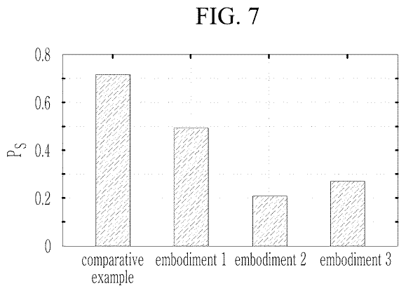

Next, FIG. 7 is a graph of the surface influence probability (Ps) of the quantum dot shell predicted through molecular dynamics simulation. The comparative example is DGtBE (diethylene glycol-mono-tert-butyl ether), Example 1 is a solvent including or consisting of compound 1 (MEEP), Example 2 is a solvent including or consisting of compound 2 (DGtBA), and Example 3 is a solvent including or consisting of compound 3 (TEGPA).

As shown in FIG. 7, through molecular dynamics simulations that predict solvent permeability and reactivity at the molecular level, the probability (Ps) of reacting and existing on the surface of quantum dots is lower in Examples 1 to 3 than in the comparative examples.

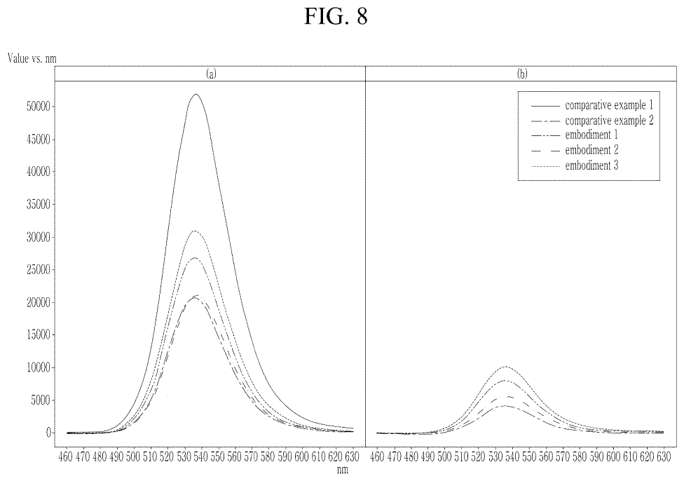

Next, FIG. 8 is a graph of luminescence intensity measurement according to solvent. FIG. 8(a) shows the luminescence intensity immediately after applying the solvent, and FIG. 8(b) shows the luminescence intensity measured after applying the solvent for 15 minutes (MIN).

Referring to FIG. 8 and Table 3 below, in the case of Comparative Example 2, it was confirmed that the luminescence intensity decreased from 40% to 8% depending on the reaction between the solvent and the quantum dots. In Embodiments 1 to 3, it was confirmed that the luminescence intensity decreased to about 15%, 11%, and 20%. For the Comparative Examples, it was confirmed that the luminescence intensity was improved.

For reference, Comparative Example 1 shows the luminescence intensity of the light-emitting layer that is not in contact with a solvent.

TABLE 3

| | | light-emitting |
|---|---|---|
| item | waiting time | strength |

| | | |
|---|---|---|
| Comparative | — | 100% |
| Example 1 | | |

| | | | |
|---|---|---|---|
| Comparative | 0 | MIN | 40% |
| Example 2 | 15 | MIN | 8% |
| Embodiment 1 | 0 | MIN | 52% |
| (compound 2) | 15 | MIN | 15% |
| Embodiment 2 | 0 | MIN | 41% |
| (compound 3) | 15 | MIN | 11% |
| Embodiment 3 | 0 | MIN | 60% |
| (compound 1) | 15 | MIN | 20% |

The metal oxide composition included in the electron transport layer in an embodiment may include a solvent including or consisting of the first compound and a metal oxide including or consisting of the second compound. At this time, the aforementioned solvent may have characteristics such as a relatively high molecular weight and polarity, and including a secondary or tertiary alcohol, which may reduce the probability of the surface reaction in which the solvent reacts with quantum dots, and the probability that the aforementioned solvent will penetrate the ligand bound to the surface of the quantum dots. According to this, the chemical reaction between the solvent and the quantum dots may be reduced, ensuring the reliability of the quantum dots, and improving the photoluminescence intensity of the light-emitting element. Although the embodiments of the invention have been described in detail above, the scope of the invention is not limited thereto, and various modifications and improvements made by those skilled in the art using the basic concepts of the invention defined in the following claims are also possible.

What is claimed is:

1. A light-emitting element comprising:
a first electrode;
a hole transport layer disposed on the first electrode;
a light-emitting layer disposed on the hole transport layer;
an electron transport layer disposed on the light-emitting layer, the electron transport layer including:
a metal oxide composition including:
a solvent including a first compound; and
a metal oxide including a second compound; and
a second electrode disposed on the electron transport layer,
wherein,
the first compound is represented by at least one of following Chemical Formulas 1 to 3: 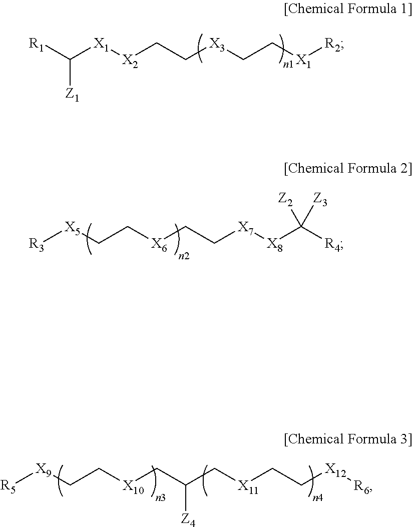
the second compound is represented by following Chemical Formula 4:
MₚO_{q} [Chemical Formula 4],
in the Chemical Formulas 1 to 3, R₁, R₂, R₃, R₄, R₅, and R₆ are each independently deuterium, a hydroxyl group, a C₁-C₂₀ alkyl group, a C₁-C₂₀ alkoxy group, a C₃-C₃₀ carbocyclic group, a C₁-C₃₀ heterocyclic group, a C₆-C₆₀ aryloxy group, a C₆-C₆₀ arylthio group, or a substituted or unsubstituted C₁-C₂₀ alkyl group or C₁-C₂₀ alkoxy group with any combinations of deuterium, the hydroxyl group, the C₁-C₂₀ alkyl group, the C₁-C₂₀ alkoxy group, the C₃-C₃₀ carbocyclic group, the C₁-C₃₀ heterocyclic group, the C₆-C₆₀ aryloxy group and the C₆-C₆₀ arylthio group,
X₁ to X₁₂ each independently represent a single bond, a substituted or unsubstituted C₁-C₆₀ alkylene group, a substituted or unsubstituted C₂-C₆₀ alkenylene group, a substituted or unsubstituted C₂-C₆₀ alkynylene group, a substituted or unsubstituted C₃-C₁ cycloalkylene group, a substituted or unsubstituted C₃-C₁ heterocycloalkenylene group, a substituted or unsubstituted C₃-C₁₀ cycloalkenylene group, or a substituted or unsubstituted C₁-C₁ heterocycloalkenylene group, or *—O—*′, where * and *′ are bonding sites with adjacent atoms,
Z₁ to Z₄ each independently represent hydrogen, deuterium, —F, —Cl, —Br, —I, a hydroxyl group, a cyano group, a nitro group, a substituted or unsubstituted C₁-C₆₀ alkyl group, a substituted or unsubstituted C₂-C₆₀₀ alkenyl group, a substituted or unsubstituted C₂-C₆₀ alkynyl group, a substituted or unsubstituted C₁-C₆₀ alkoxy group, a substituted or unsubstituted C₃-C₆₀ carbocyclic group, a substituted or unsubstituted C₁-C₆₀ heterocyclic group, a substituted or unsubstituted C₆-C₆₀ aryloxy group, or a substituted or unsubstituted C₆-C₆₀ arylthio group,
n₁, n₂, n₃, and n₄ are each independently an integer from 0 to 5,
in the Chemical Formula 4, M is Zn, Ti, Zr, Sn, W, Ta, Ni, Mo, Cu or V, and
in the Chemical Formula 4, p and q are independently one of the integers of 1 to 5.

2. The light-emitting element of claim 1, wherein
a molecular weight of the first compound is 140 grams per mol or more.

3. The light-emitting element of claim 1, wherein
a ratio of a number of oxygen atoms to a total number of carbon atoms and oxygen atoms included in the first compound is 0.3 or more.

4. The light-emitting element of claim 1, wherein
the first compound comprises at least one of a secondary alcohol and a tertiary alcohol.

5. The light-emitting element of claim 1, wherein
the first compound comprises at least one of following Compounds 1 to 3:

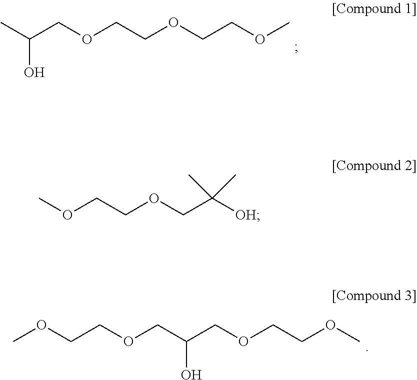

6. The light-emitting element of claim 5, wherein
the first compound further comprises any one of following compounds 4 to 28:

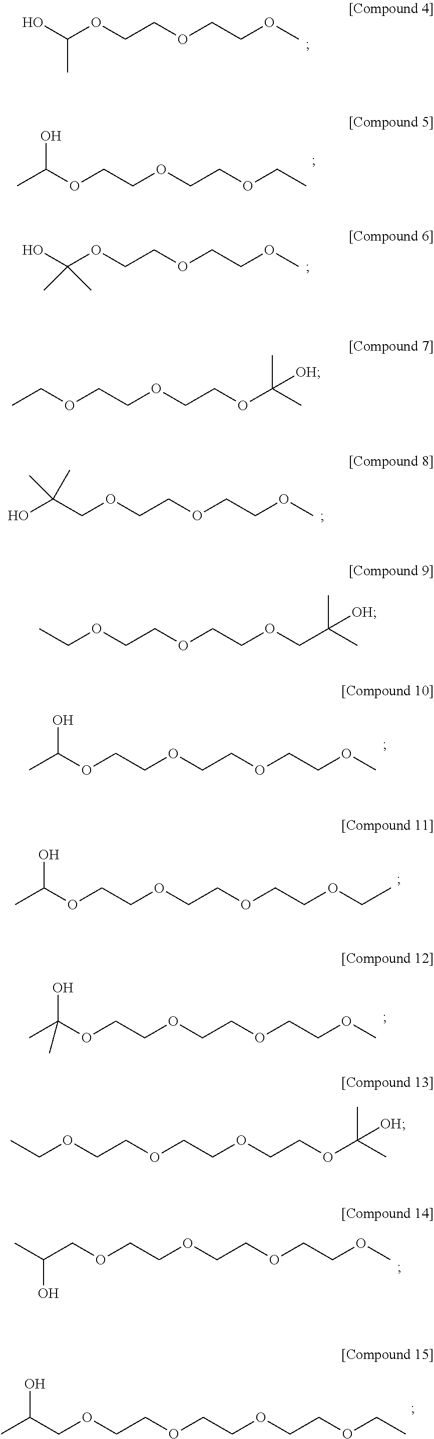

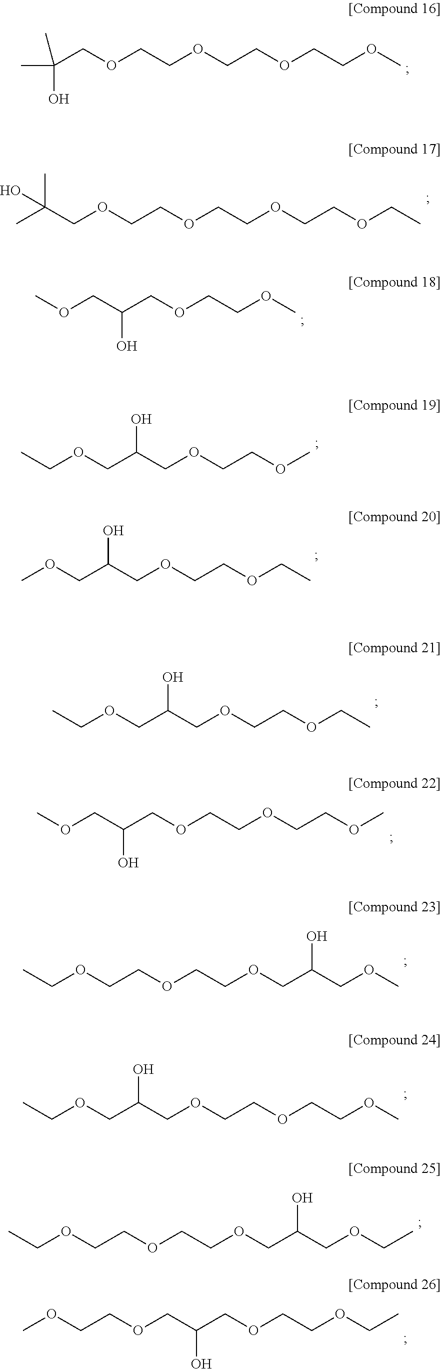

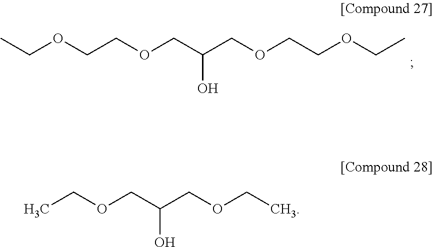

7. The light-emitting element of claim 1, wherein
the second compound is a zinc-containing oxide.

8. The light-emitting element of claim 7, wherein
the second compound comprises at least one of ZnO, ZnMgO, ZnAIO, ZnSiO, ZnYbO, TiO₂, WO₃, W₂O₃, and WO₂.

9. A light-emitting element comprising:
a first electrode;
a hole transport layer disposed on the first electrode;
a light-emitting layer disposed on the hole transport layer;
an electron transport layer disposed on the light-emitting layer, the electron transport layer including:
a metal oxide composition including:
a solvent including:
a first compound including at least one of a secondary alcohol and a tertiary alcohol; and
a metal oxide; and
a second electrode disposed on the electron transport layer,
wherein
a molecular weight of the first compound is 140 grams per or more, and
a ratio of a number of oxygen atoms to a total number of carbon atoms and oxygen atoms included in the first compound is 0.3 or more.

10. The light-emitting element of claim 9, wherein
the first compound comprises at least one of the compounds represented by following Chemical Formulas 1 to 3: 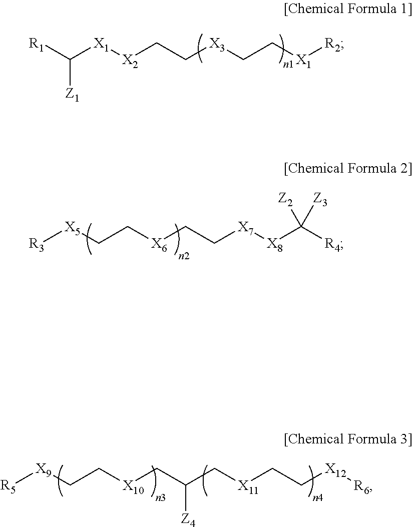
in the Chemical Formulas 1 to 3, R₁, R₂, R₃, R₄, R₅, and R₆ are each independently deuterium, a hydroxyl group, a C₁-C₂₀ alkyl group, a C₁-C₂₀ alkoxy group, a C₃-C₃₀ carbocyclic group, a C₁-C₃₀ heterocyclic group, a C₆-C₃₀ aryloxy group, a C₆-C₃₀ arylthio group, or a substituted or unsubstituted C₁-C₂₀ alkyl group or C₁-C₂₀ alkoxy group with any combinations of deuterium, the hydroxyl group, the C₁-C₂₀ alkyl group, the C₁-C₂₀ alkoxy group, the C₃-C₃₀ carbocyclic group, the C₁-C₃₀ heterocyclic group, the C₆-C₆₀ aryloxy group and the C₆-C₆₀ arylthio group,
X₁ to X₁₂ each independently represent a single bond, a substituted or unsubstituted C₁-C₆₀ alkylene group, a substituted or unsubstituted C₂-C₆₀ alkenylene group, a substituted or unsubstituted C₂-C₆₀ alkynylene group, a substituted or unsubstituted C₃-C₁₀ cycloalkylene group, a substituted or unsubstituted C₃-C₁₀ heterocycloalkenylene group, a substituted or unsubstituted C₃-C₁₀ cycloalkenylene group, or a substituted or unsubstituted C₁-C₁₀ heterocycloalkenylene group, or *—O—*′, where * and *′ are the bonding sites with adjacent atoms,
Z₁ to Z₄ each independently represent hydrogen, deuterium, —F, —Cl, —Br, —I, a hydroxyl group, a cyano group, a nitro group, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₆₀ carbocyclic group, a substituted or unsubstituted C₁-C₆₀ heterocyclic group, a substituted or unsubstituted C₆-C₆₀ aryloxy group, and a substituted or unsubstituted C₆-C₆₀ arylthio group, and n₁, n₂, n₃, and n₄ each independently represent an integer from 0 to 5.

11. The light-emitting element of claim 10, wherein
the metal oxide includes a second compound,
the second compound is a zinc-containing oxide.

12. The light-emitting element of claim 10, wherein
the metal oxide includes a second compound, and
the second compound comprises at least one of ZnO, ZnMgO, ZnAIO, ZnSiO, ZnYbO, TiO₂, WO₃, W₂O₃, and WO₂.

13. A light-emitting element substrate, comprising:
a substrate;
a transistor disposed on the substrate; and
a light-emitting element electrically connected to the transistor, the light-emitting element comprising:
a first electrode,
a hole transport layer disposed on the first electrode,
a light-emitting layer disposed on the hole transport layer,
an electron transport layer disposed on the light-emitting layer, the electron transport layer including:
a metal oxide composition including:
a solvent including a first compound; and
a metal oxide including a second compound, and
a second electrode disposed on the electron transport layer,
wherein
the first compound is represented by at least one of following Chemical Formulas 1 to 3: 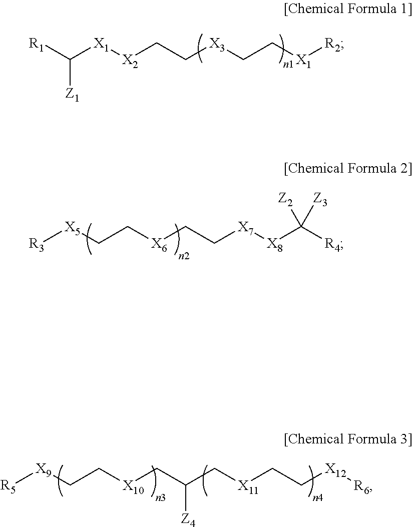
the second compound is represented by following Chemical Formula 4:
MₚO_{q} [Chemical Formula 4],
in the Chemical Formulas 1 to 3, R₁, R₂, R₃, R₄, R₅, and R₆ are each independently deuterium, a hydroxyl group, a C₁-C₂₀ alkyl group, a C₁-C₂₀ alkoxy group, a C₃-C₃₀ carbocyclic group, a C₁-C₃₀ heterocyclic group, a C₆-C₃₀ aryloxy group, a C₆-C₃₀ arylthio group, or a substituted or unsubstituted combination C₁-C₂₀ alkyl group or C₁-C₂₀ alkoxy group with any combinations of deuterium, the hydroxyl group, the C₁-C₂₀ alkyl group, the C₁-C₂₀ alkoxy group, the C₃-C₃₀ carbocyclic group, the C₁-C₃₀ heterocyclic group, the C₆-C₃₀ aryloxy group and the C₆-C₃₀ arylthio group,
X₁ to X₁₂ each independently represent a single bond, a substituted or unsubstituted C₁-C₆₀ alkylene group, a substituted or unsubstituted C₂-C₆₀ alkenylene group, a substituted or unsubstituted C₂-C₆₀ alkynylene group, a substituted or unsubstituted C₃-C₁₀ cycloalkylene group, a substituted or unsubstituted C₃-C₁₀ heterocycloalkylene group, a substituted or unsubstituted C₃-C₁₀ cycloalkenylene group, or a substituted or unsubstituted C₁-C₁₀ heterocycloalkenylene group, or *—O—*′, where * and *′ are bonding sites with neighboring atoms,
Z₁ to Z₄ each independently represent hydrogen, deuterium, —F, —Cl, —Br, —I, a hydroxyl group, a cyano group, a nitro group, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₆₀ carbocyclic group, a substituted or unsubstituted C₁-C₆₀ heterocyclic group, a substituted or unsubstituted C₆-C₆₀ aryloxy group, or a substituted or unsubstituted C₆-C₆₀ arylthio group,
n₁, n₂, n₃, and n₄ are each independently an integer from 0 to 5,
in the Chemical Formula 4, M is Zn, Ti, Zr, Sn, W, Ta, Ni, Mo, Cu or V, and
in the Chemical Formula 4, p and q are independently one of the integers of 1 to 5.

14. The light-emitting element of claim 13, wherein
a molecular weight of the first compound is 140 g/mol or more.

15. The light-emitting element of claim 13, wherein
a ratio of a number of oxygen atoms to a total number of carbon atoms and oxygen atoms included in the first compound is 0.3 or more.

16. The light-emitting element of claim 13, wherein
the first compound includes at least one of a secondary alcohol and a tertiary alcohol.

17. The light-emitting element of claim 13, wherein
the first compound includes at least one of following Compounds 1 to 3:

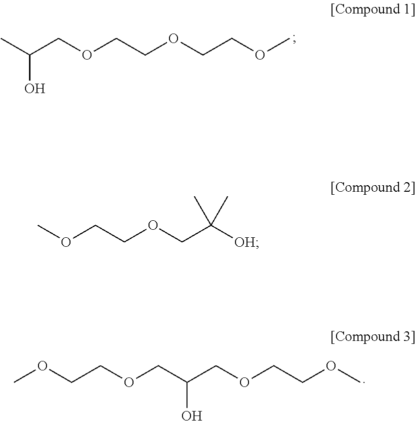

18. The light-emitting element of claim 13, wherein
the second compound is a zinc-containing oxide.

19. The light-emitting element of claim 18, wherein
the second compound is represented by following Chemical Formula 4-1:
Zn₍₁₋ᵣ₎M′ᵣO [Chemical Formula 4-1],
in the Chemical Formula 4-1, M′ is Mg, Co, Ni, Zr, Mn, Sn, Y, Al, or any combinations thereof, and r in the Chemical Formula 4-1 is a number greater than 0 and equal to or less than 0.5.

20. The light-emitting element of claim 18, wherein
the second compound includes at least one of ZnO, ZnMgO, ZnAIO, ZnSiO, ZnYbO, TiO₂, WO₃, W₂O₃, and WO₂.
